(19) United States
(12) Patent Application Publication
(10) Pub. No.: US 2023/0307383 A1
(43) Pub. Date: Sep. 28, 2023

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kodai OGAWA, Oita Oita (JP); Hiroshi ISHITANI, Oita Oita (JP)

(21) Appl. No.: 17/902,610

(22) Filed: Sep. 2, 2022

(30) Foreign Application Priority Data
Mar. 24, 2022 (JP) 2022-049039

(51) Int. Cl. H01L 23/00; H01L 23/58

(52) U.S. Cl. CPC H01L 23/564; H01L 23/562; H01L 23/585

(57) ABSTRACT

A semiconductor device according to an embodiment includes: an element region; and an outer peripheral region surrounding the element region, the outer peripheral region including a semiconductor layer having a first face and a second face opposite to the first face, a first annular conductor provided on a side of the first face with respect to the semiconductor layer and surrounding the element region, a second annular conductor provided on the side of the first face with respect to the semiconductor layer and surrounding the first annular conductor, and at least one first connection conductor provided between the first annular conductor and the second annular conductor and connected to the first annular conductor and the second annular conductor.

### CROSS-REFERENCE TO RELATED APPLICATION

This application is based upon and claims the benefit of priority from Japanese Patent Application No. 2022-049039, filed on Mar. 24, 2022, the entire contents of which are incorporated herein by reference.

### FIELD

Embodiments described herein relate generally to a semiconductor device.

### BACKGROUND

In a semiconductor chip, a chip ring (seal ring) surrounding an element region may be provided in an outer peripheral region surrounding the element region. The chip ring is formed using a contact layer or a wiring layer constituting the semiconductor chip. Providing the chip ring prevents, for example, intrusion of moisture and movable ions from the outside into the element region, and thus, the reliability of the semiconductor chip is improved.

### BRIEF DESCRIPTION OF THE DRAWINGS

FIG. 1 is a schematic top view of a semiconductor device according to a first embodiment;

FIGS. 2A and 2B are enlarged schematic cross-sectional views of the semiconductor device according to the first embodiment;

FIG. 3 is a schematic top view of a semiconductor device according to a comparative example;

FIG. 4 is an explanatory diagram of a problem of the semiconductor device according to the comparative example;

FIG. 5 is an explanatory diagram for describing functions and effects of the semiconductor device according to the first embodiment;

FIG. 6 is a schematic top view of a semiconductor device according to a second embodiment;

FIG. 7 is an explanatory diagram for describing functions and effects of the semiconductor device according to the second embodiment; and

FIG. 8 is a schematic top view of a semiconductor device according to a modification of the second embodiment.

### DETAILED DESCRIPTION

A semiconductor device according to one aspect of the present disclosure includes: an element region; and an outer peripheral region surrounding the element region, the outer peripheral region including a semiconductor layer having a first face and a second face opposite to the first face, a first annular conductor provided on a side of the first face with respect to the semiconductor layer and surrounding the element region, a second annular conductor provided on the side of the first face with respect to the semiconductor layer and surrounding the first annular conductor, and at least one first connection conductor provided between the first annular conductor and the second annular conductor and connected to the first annular conductor and the second annular conductor.

In the present specification, the same or similar components are denoted by the same reference numerals, and redundant description may be omitted.

In the present specification, in order to indicate a positional relationship of components and the like, an upward direction in the drawings may be described by the term “upper”, and a downward direction in the drawings may be described by the term “lower”. In the present specification, the concepts of “upper” and “lower” are not necessarily terms indicating the relationship with the direction of gravity.

### First Embodiment

A semiconductor device according to the first embodiment includes: an element region; and an outer peripheral region surrounding the element region, the outer peripheral region including a semiconductor layer having a first face and a second face opposite to the first face, a first annular conductor provided on a side of the first face with respect to the semiconductor layer and surrounding the element region, a second annular conductor provided on the side of the first face with respect to the semiconductor layer and surrounding the first annular conductor, and at least one first connection conductor provided between the first annular conductor and the second annular conductor and connected to the first annular conductor and the second annular conductor.

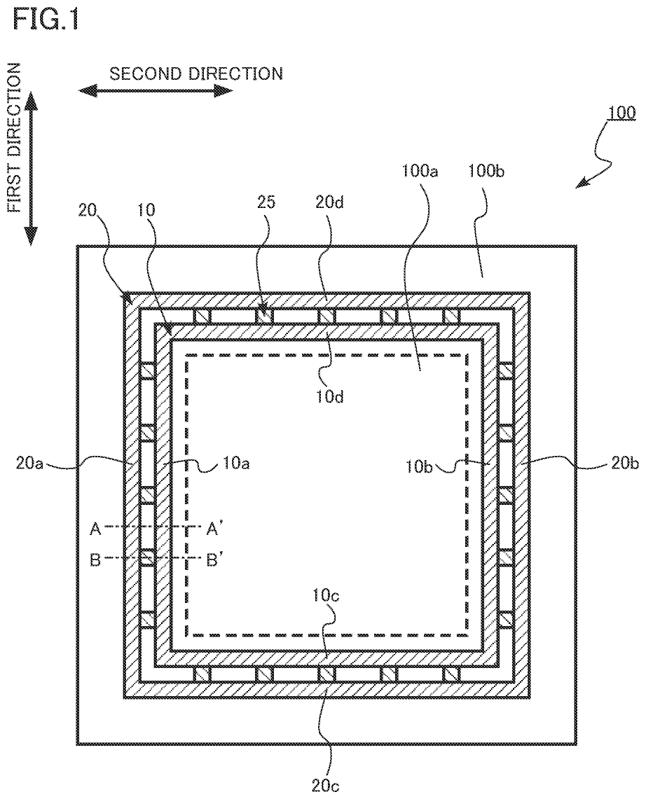

FIG. 1 is a schematic top view of the semiconductor device according to the first embodiment. The semiconductor device according to the first embodiment is a semiconductor chip 100. The semiconductor chip 100 includes an element region 100a and an outer peripheral region 100b.

The element region 100a includes, for example, semiconductor elements such as a transistor or a diode (not illustrated). The element region 100a includes, for example, a contact layer and a wiring layer for electrically connecting the semiconductor elements. The element region 100a is surrounded by the outer peripheral region 100b.

The outer peripheral region 100b surrounds the element region 100a. The outer peripheral region 100b is provided with, for example, a termination structure (not illustrated). The termination structure has a function of improving the breakdown voltage of the semiconductor chip 100.

The outer peripheral region 100b includes a first chip ring 10 (first annular conductor), a second chip ring 20 (second annular conductor), and a first connection conductor 25.

The first chip ring 10 surrounds the element region 100a. The first chip ring 10 includes a first region 10a, a second region 10b, a third region 10c, and a fourth region 10d.

The first region 10a and the second region 10b extend in a first direction. The element region 100a is provided between the first region 10a and the second region 10b.

The third region 10c and the fourth region 10d extend in a second direction. The second direction is orthogonal to the first direction. The element region 100a is provided between the third region 10c and the fourth region 10d.

The second chip ring 20 surrounds the element region 100a. The second chip ring 20 surrounds the first chip ring 10. The second chip ring 20 includes a fifth region 20a, a sixth region 20b, a seventh region 20c, and an eighth region 20d.

The fifth region 20a and the sixth region 20b extend in the first direction. The element region 100a is provided between the fifth region 20a and the sixth region 20b.

The seventh region 20c and the eighth region 20d extend in the second direction. The element region 100a is provided between the seventh region 20c and the eighth region 20d.

The fifth region 20a is adjacent to the first region 10a. The sixth region 20b is adjacent to the second region 10b. The seventh region 20c is adjacent to the third region 10c. The eighth region 20d is adjacent to the fourth region 10d.

The first connection conductor 25 is provided between the first chip ring 10 and the second chip ring 20. The first connection conductor 25 is connected to the first chip ring 10 and the second chip ring 20.

The first connection conductor 25 is provided between the first region 10a and the fifth region 20a. The first connection conductor 25 is provided between the second region 10b and the sixth region 20b. The first connection conductor 25 is provided between the third region 10c and the seventh region 20c. The first connection conductor 25 is provided between the fourth region 10d and the eighth region 20d.

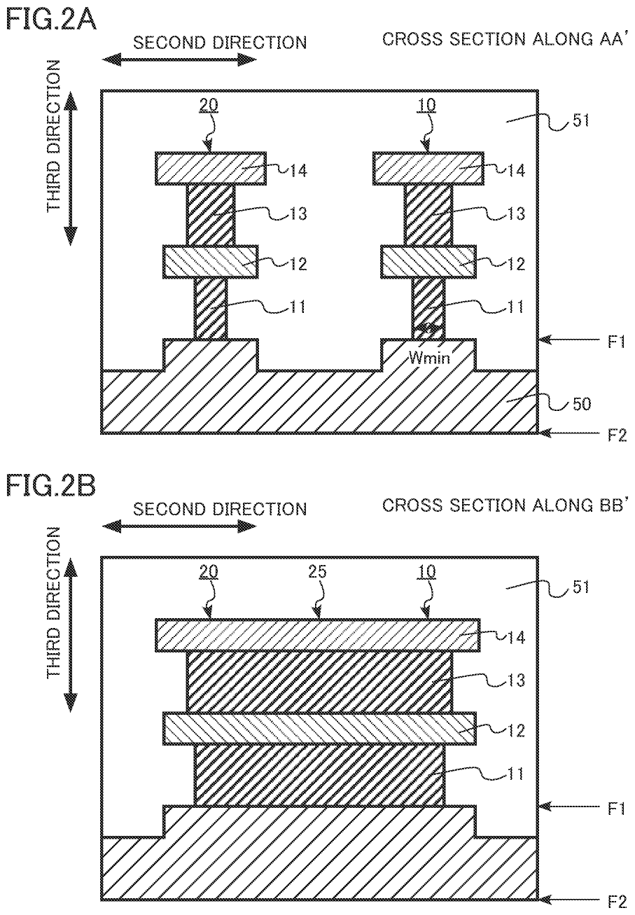

FIGS. 2A and 2B are enlarged schematic cross-sectional views of the semiconductor device according to the first embodiment. FIGS. 2A and 2B are cross-sectional views of the outer peripheral region 100b.

FIG. 2A illustrates a cross section taken along a line AA′ in FIG. 1. FIG. 2B illustrates a cross section taken along a line BB′ in FIG. 1.

The outer peripheral region 100b includes a semiconductor layer 50 and an interlayer insulating layer 51 (insulating layer). The semiconductor layer 50 includes a first face F1 and a second face F2. The second face F2 faces the first face F1.

The first direction is parallel to the first face F1. The second direction is parallel to the first face F1. The third direction is perpendicular to the first face F1.

The semiconductor layer 50 is made of, for example, single crystal silicon.

The interlayer insulating layer 51 is provided on the first face F1 side with respect to the semiconductor layer 50. The interlayer insulating layer 51 is provided on the semiconductor layer 50. The interlayer insulating layer 51 is provided between the first chip ring 10 and the second chip ring 20.

The interlayer insulating layer 51 has, for example, a stacked structure of a plurality of insulating layers (not illustrated). The interlayer insulating layer 51 is made of, for example, an oxide, an oxynitride, or a nitride. The interlayer insulating layer 51 contains, for example, silicon oxide or silicon nitride.

The first chip ring 10 is provided on the first face F1 side with respect to the semiconductor layer 50. The first chip ring 10 is provided on the semiconductor layer 50. The first chip ring 10 is in contact with the semiconductor layer 50. The first chip ring 10 is provided in the interlayer insulating layer 51.

The first chip ring 10 includes a first contact layer 11 (first layer), a first wiring layer 12 (second layer), a second contact layer 13, and a second wiring layer 14. The first contact layer 11, the first wiring layer 12, the second contact layer 13, and the second wiring layer 14 are stacked in this order in the third direction.

The first chip ring 10 is a conductor. The first contact layer 11, the first wiring layer 12, the second contact layer 13, and the second wiring layer 14 are conductors.

For example, the chemical composition of the first contact layer 11 is different from the chemical composition of the first wiring layer 12. The first contact layer 11 is made of, for example, tungsten (W). In addition, the first wiring layer 12 is made of, for example, copper (Cu).

The minimum width (Wmin in FIG. 2A) of the first chip ring 10 is, for example, equal to or less than 1.0 μm. The minimum width Wmin of the first chip ring 10 is, for example, the width of the first contact layer 11 in the second direction.

The second chip ring 20 is provided on the first face F1 side with respect to the semiconductor layer 50. The second chip ring 20 is provided on the semiconductor layer 50. The second chip ring 20 is in contact with the semiconductor layer 50. The second chip ring 20 is provided in the interlayer insulating layer 51.

The second chip ring 20 includes the first contact layer 11, the first wiring layer 12, the second contact layer 13, and the second wiring layer 14. The first contact layer 11, the first wiring layer 12, the second contact layer 13, and the second wiring layer 14 are stacked in this order in the third direction.

The second chip ring 20 is a conductor. The first contact layer 11, the first wiring layer 12, the second contact layer 13, and the second wiring layer 14 are conductors. The second chip ring 20 and the first chip ring 10 are made of the same material.

The minimum width of the second chip ring 20 is, for example, equal to or less than 1.0 μm. The minimum width Wmin of the second chip ring 20 is, for example, the width of the first contact layer 11 in the second direction.

The first connection conductor 25 is provided on the first face F1 side with respect to the semiconductor layer 50. The first connection conductor 25 is provided on the semiconductor layer 50. The first connection conductor 25 is in contact with the semiconductor layer 50. The first connection conductor 25 is provided in the interlayer insulating layer 51.

The first connection conductor 25 includes the first contact layer 11, the first wiring layer 12, the second contact layer 13, and the second wiring layer 14. The first contact layer 11, the first wiring layer 12, the second contact layer 13, and the second wiring layer 14 are stacked in this order in the third direction.

The first connection conductor 25 is a conductor. The first contact layer 11, the first wiring layer 12, the second contact layer 13, and the second wiring layer 14 are conductors. The first connection conductor 25 and the first chip ring 10 are made of the same material. The first connection conductor 25 and the second chip ring 20 are made of the same material.

Next, functions and effects of the semiconductor chip 100 according to the first embodiment will be described.

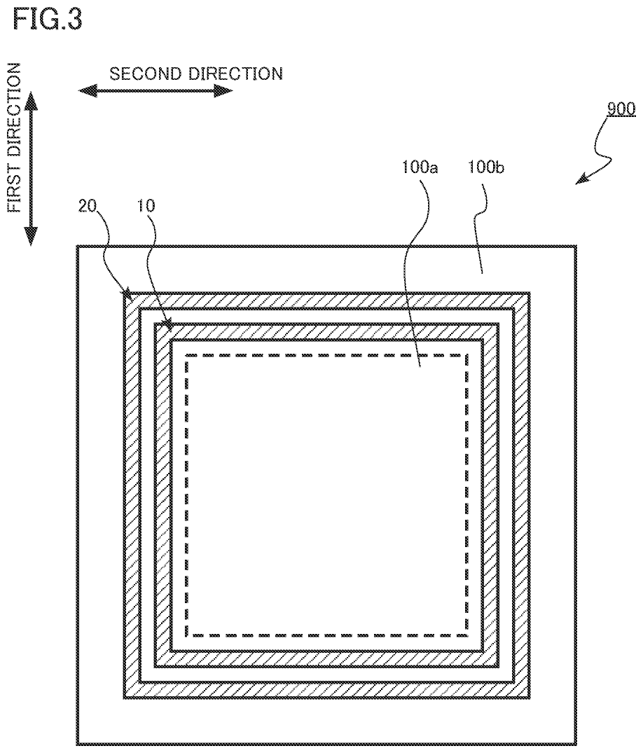

FIG. 3 is a schematic top view of a semiconductor device according to a comparative example. FIG. 3 is a diagram corresponding to FIG. 1 of the first embodiment.

The semiconductor device according to the comparative example is a semiconductor chip 900. The semiconductor chip 900 according to the comparative example is different from the semiconductor chip 100 according to the first embodiment in that the outer peripheral region 100b does not include the first connection conductor 25.

Similar to the semiconductor chip 100 according to the first embodiment, the semiconductor chip 900 according to the comparative example includes a first chip ring 10 and a second chip ring 20 in an outer peripheral region 100b. Providing the first chip ring 10 and the second chip ring 20 prevents intrusion of moisture and movable ions from the outside into an element region 100a, and thus, the reliability of the semiconductor chip 900 is improved.

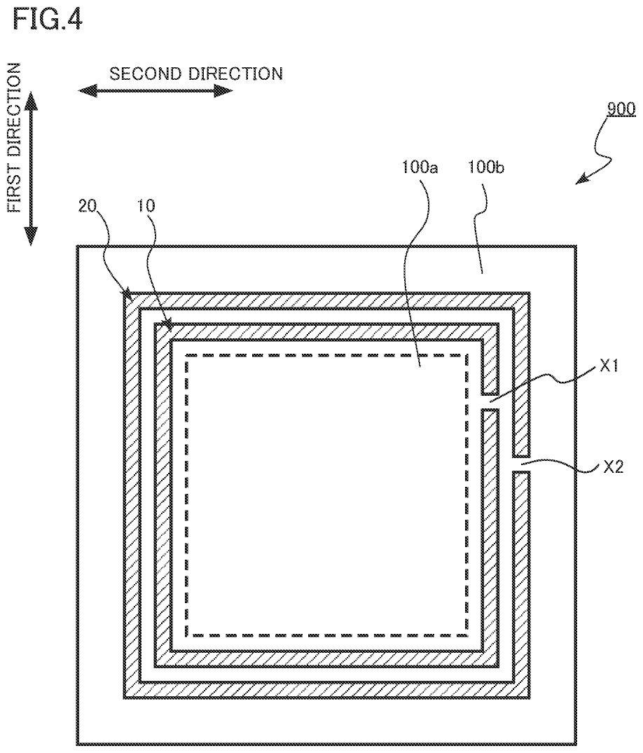

FIG. 4 is an explanatory diagram of a problem of the semiconductor device according to the comparative example. The first chip ring 10 and the second chip ring 20 of the semiconductor chip 900 may have, for example, a pattern unformed region X1 or a pattern unformed region X2. The pattern unformed region X1 and the pattern unformed region X2 are generated due to, for example, a collapse of a resist pattern during, for example, the formation of patterns of the first chip ring 10 and the second chip ring 20 by a photolithography method. The collapse of the resist pattern occurs notably as the size of the pattern decreases. For example, when the pattern width and the pattern interval are equal to or less than 1.0 μm, the collapse of the resist pattern occurs notably.

When the pattern unformed region X1 and the pattern unformed region X2 are generated, moisture and movable ions may enter the element region 100a from the outside via the pattern unformed region X1 and the pattern unformed region X2. Therefore, the reliability of the semiconductor chip 900 may be lowered.

The semiconductor chip 100 according to the first embodiment includes the first connection conductor 25 between the first chip ring 10 and the second chip ring 20. The pattern of the first connection conductor 25 functions as a support pattern that supports a resist when the patterns of the first chip ring 10 and the second chip ring 20 are formed using a photolithography method.

Therefore, the collapse of the resist pattern during the formation of the patterns of the first chip ring 10 and the second chip ring 20 with the photolithography method is suppressed. Accordingly, the generation of the pattern unformed region is suppressed, and the intrusion of moisture and movable ions from the outside into the element region 100a is prevented. Thus, the reliability of the semiconductor chip 100 is improved.

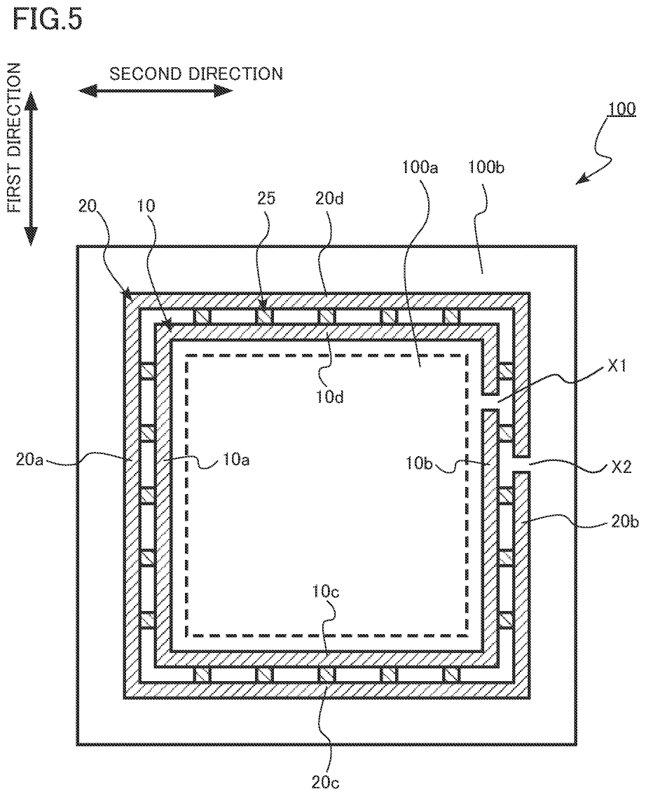

FIG. 5 is an explanatory diagram for describing functions and effects of the semiconductor device according to the first embodiment.

Due to the first connection conductor 25 provided between the first chip ring 10 and the second chip ring 20, the semiconductor chip 100 according to the first embodiment can block a path of entry of moisture and movable ions into the element region 100a from the outside, even if the pattern unformed region X1 or the pattern unformed region X2 is generated as illustrated in FIG. 5. Accordingly, the intrusion of moisture and movable ions from the outside into the element region 100a is prevented, whereby the reliability of the semiconductor chip 100 is improved.

As described above, according to the first embodiment, a semiconductor device capable of preventing intrusion of moisture or movable ions from the outside into the element region 100a and having improved reliability can be obtained.

### Second Embodiment

A semiconductor device according to the second embodiment is different from the semiconductor device according to the first embodiment in that the outer peripheral region further includes a third annular conductor provided on the first face side with respect to the semiconductor layer and surrounding the second annular conductor, and at least one second connection conductor provided between the second annular conductor and the third annular conductor and connected to the second annular conductor and the third annular conductor. In the following, the description overlapping the description of the first embodiment may be partially omitted.

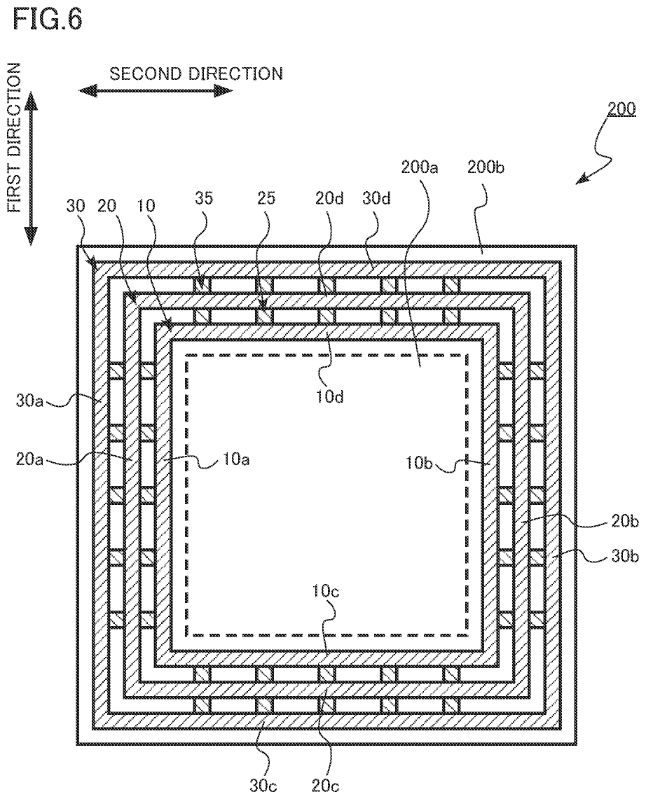

FIG. 6 is a schematic top view of a semiconductor device according to the second embodiment. The semiconductor device according to the second embodiment is a semiconductor chip 200. The semiconductor chip 200 includes an element region 200a and an outer peripheral region 200b.

The outer peripheral region 200b includes a first chip ring 10 (first annular conductor), a second chip ring 20 (second annular conductor), a third chip ring 30 (third annular conductor), a first connection conductor 25, and a second connection conductor 35.

The third chip ring 30 surrounds the element region 200a. The third chip ring 30 surrounds the second chip ring 20. The third chip ring 30 includes a ninth region 30a, a tenth region 30b, an eleventh region 30c, and a twelfth region 30d.

The ninth region 30a and the tenth region 30b extend in the first direction. The element region 200a is provided between the ninth region 30a and the tenth region 30b.

The eleventh region 30c and the twelfth region 30d extend in the second direction. The element region 200a is provided between the eleventh region 30c and the twelfth region 30d.

The ninth region 30a is adjacent to the fifth region 20a. The tenth region 30b is adjacent to the sixth region 20b. The eleventh region 30c is adjacent to the seventh region 20c. The twelfth region 30d is adjacent to the eighth region 20d.

The second connection conductor 35 is provided between the second chip ring 20 and the third chip ring 30. The second connection conductor 35 is connected to the second chip ring 20 and the third chip ring 30.

The second connection conductor 35 is provided between the fifth region 20a and the ninth region 30a. The second connection conductor 35 is provided between the sixth region 20b and the tenth region 30b. The second connection conductor 35 is provided between the seventh region 20c and the eleventh region 30c. The second connection conductor 35 is provided between the eighth region 20d and the twelfth region 30d.

The third chip ring 30 is provided on the first face F1 side with respect to the semiconductor layer 50. The third chip ring 30 is provided on the semiconductor layer 50. The third chip ring 30 is in contact with the semiconductor layer 50. The third chip ring 30 is provided in the interlayer insulating layer 51.

The third chip ring 30 includes a first contact layer 11, a first wiring layer 12, a second contact layer 13, and a second wiring layer 14. The first contact layer 11 (first layer), the first wiring layer 12 (second layer), the second contact layer 13, and the second wiring layer 14 are stacked in this order in the third direction.

The third chip ring 30 is a conductor. The first contact layer 11, the first wiring layer 12, the second contact layer 13, and the second wiring layer 14 are conductors. The third chip ring 30, the first chip ring 10, and the second chip ring 20 are made of the same material.

The minimum width of the third chip ring 30 is, for example, equal to or less than 1.0 μm. The minimum width Wmin of the third chip ring 30 is, for example, the width of the first contact layer 11 in the second direction.

The second connection conductor 35 is provided on the first face F1 side with respect to the semiconductor layer 50. The second connection conductor 35 is provided on the semiconductor layer 50. The second connection conductor 35 is in contact with the semiconductor layer 50. The second connection conductor 35 is provided in the interlayer insulating layer 51.

The second connection conductor 35 includes the first contact layer 11, the first wiring layer 12, the second contact layer 13, and the second wiring layer 14. The first contact layer 11, the first wiring layer 12, the second contact layer 13, and the second wiring layer 14 are stacked in this order in the third direction.

The second connection conductor 35 is a conductor. The first contact layer 11, the first wiring layer 12, the second contact layer 13, and the second wiring layer 14 are conductors. The second connection conductor 35 and the second chip ring 20 are made of the same material. The second connection conductor 35 and the third chip ring 30 are made of the same material.

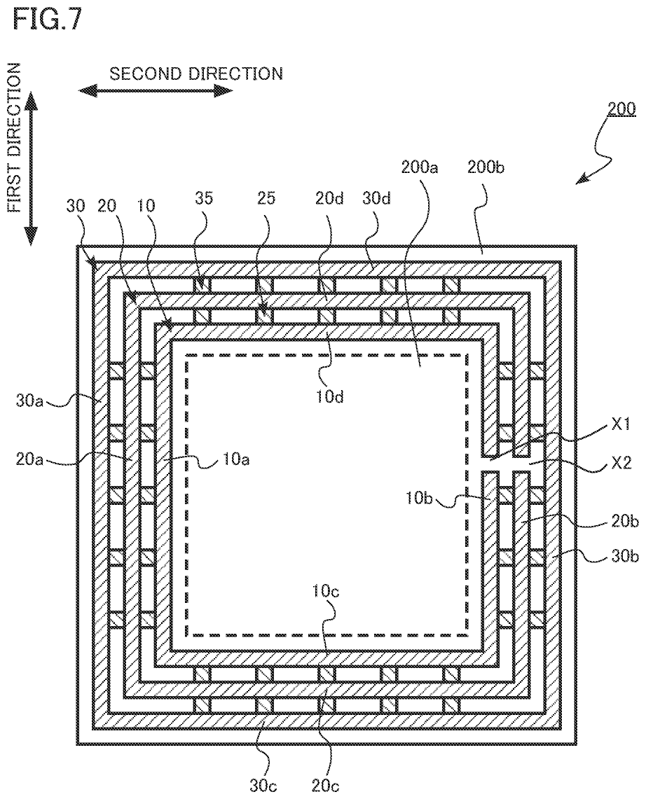

FIG. 7 is an explanatory diagram for describing functions and effects of the semiconductor device according to the second embodiment.

Since the semiconductor chip 200 according to the second embodiment includes the first connection conductor 25 between the first chip ring 10 and the second chip ring 20, the reliability of the semiconductor chip 200 is improved as in the semiconductor chip 100 according to the first embodiment.

In addition, due to the third chip ring 30 being provided, the semiconductor chip 200 according to the second embodiment can block a path of entry of moisture and movable ions into the element region 200a from the outside, even if the pattern unformed region X1 and the pattern unformed region X2 are generated adjacent to each other in the first chip ring 10 and the second chip ring 20 as illustrated in FIG. 7. Accordingly, the intrusion of moisture and movable ions from the outside into the element region 200a is prevented, whereby the reliability of the semiconductor chip 200 is further improved.

(Modification)

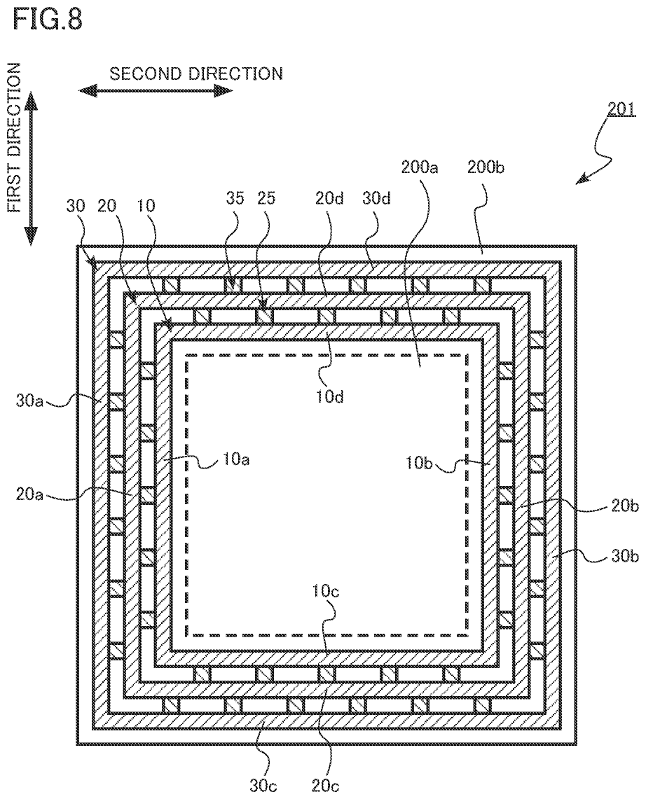

FIG. 8 is a schematic top view of a semiconductor device according to a modification of the second embodiment. The semiconductor device according to the modification of the second embodiment is a semiconductor chip 201. The semiconductor chip 201 includes an element region 200a and an outer peripheral region 200b.

The semiconductor chip 201 according to the modification is different from the semiconductor chip 200 according to the second embodiment in that a plurality of at least one first connection conductors is repeatedly provided in the first direction between the first region and the fifth region, a plurality of at least one second connection conductors is repeatedly provided in the first direction between the fifth region and the ninth region, and the plurality of at least one first connection conductors and the plurality of at least one second connection conductors are alternately disposed in the first direction.

The semiconductor chip 201 includes a plurality of first connection conductors 25 repeatedly provided in the first direction between the first region 10a and the fifth region 20a. In addition, the semiconductor chip 201 includes a plurality of second connection conductors 35 repeatedly provided in the first direction between the fifth region 20a and the ninth region 30a. In the first direction, the plurality of first connection conductors 25 and the plurality of second connection conductors 35 are alternately displaced.

In the semiconductor chip 201, the plurality of first connection conductors 25 and the plurality of second connection conductors 35 are alternately displaced, so that the pattern of the first connection conductors 25 and the pattern of the second connection conductors 35 more robustly function as a support pattern for supporting the resist during the formation of the pattern of the first chip ring 10, the second chip ring 20, or the third chip ring 30 using the photolithography method.

Therefore, collapse of the resist pattern during the formation of the patterns of the first chip ring 10, the second chip ring 20, and the third chip ring 30 with the photolithography method is further suppressed. Accordingly, the generation of the pattern unformed region is further suppressed, and the intrusion of moisture and movable ions from the outside into the element region 200a is prevented. Thus, the reliability of the semiconductor chip 201 is further improved.

As described above, according to the second embodiment and the modification, a semiconductor device capable of preventing intrusion of moisture or movable ions from the outside into the element region 200a and having improved reliability can be obtained.

The first and second embodiments have described, as an example, the case where the first chip ring 10, the second chip ring 20, and the first connection conductor 25 are constituted by four layers which are the first contact layer 11, the first wiring layer 12, the second contact layer 13, and the second wiring layer 14. However, the first chip ring 10, the second chip ring 20, and the first connection conductor 25 may be constituted by, for example, three layers or less or five layers or more.

The first and second embodiments have described, as an example, the case where the first connection conductor 25 is formed using all of the four layers which are the first contact layer 11, the first wiring layer 12, the second contact layer 13, and the second wiring layer 14. However, the first connection conductor 25 may include at least one layer among the first contact layer 11, the first wiring layer 12, the second contact layer 13, and the second wiring layer 14. In other words, the first connection conductor 25 may not include one or more layers among the first contact layer 11, the first wiring layer 12, the second contact layer 13, and the second wiring layer 14.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
an element region; and
an outer peripheral region surrounding the element region,
the outer peripheral region including
a semiconductor layer having a first face and a second face opposite to the first face,
a first annular conductor provided on a side of the first face with respect to the semiconductor layer and surrounding the element region,
a second annular conductor provided on the side of the first face with respect to the semiconductor layer and surrounding the first annular conductor, and
at least one first connection conductor provided between the first annular conductor and the second annular conductor and connected to the first annular conductor and the second annular conductor.

2. The semiconductor device according to claim 1, wherein the first annular conductor, the second annular conductor, and the at least one first connection conductor are made of a same material.

3. The semiconductor device according to claim 1, wherein the first annular conductor is in contact with the semiconductor layer, the second annular conductor is in contact with the semiconductor layer, and the at least one first connection conductor is in contact with the semiconductor layer.

4. The semiconductor device according to claim 1, wherein
the first annular conductor includes: a first region extending in a first direction parallel to the first face; a second region extending in the first direction, the element region being provided between the first region and the second region; a third region parallel to the first face and extending in a second direction perpendicular to the first direction; and a fourth region extending in the second direction, the element region being provided between the third region and the fourth region,
the second annular conductor includes a fifth region adjacent to the first region, a sixth region adjacent to the second region, a seventh region adjacent to the third region, and an eighth region adjacent to the fourth region, and
the at least one first connection conductor is provided between the first region and the fifth region, between the second region and the sixth region, between the third region and the seventh region, and between the fourth region and the eighth region.

5. The semiconductor device according to claim 1, wherein
the outer peripheral region further includes
a third annular conductor provided on the side of the first face with respect to the semiconductor layer and surrounding the second annular conductor; and
at least one second connection conductor provided between the second annular conductor and the third annular conductor and connected to the second annular conductor and the third annular conductor.

6. The semiconductor device according to claim 5, wherein
the first annular conductor includes: a first region extending in a first direction parallel to the first face; a second region extending in the first direction, the element region being provided between the first region and the second region; a third region parallel to the first face and extending in a second direction perpendicular to the first direction; and a fourth region extending in the second direction, the element region being provided between the third region and the fourth region,
the second annular conductor includes a fifth region adjacent to the first region, a sixth region adjacent to the second region, a seventh region adjacent to the third region, and an eighth region adjacent to the fourth region,
the third annular conductor includes a ninth region adjacent to the fifth region, a tenth region adjacent to the sixth region, an eleventh region adjacent to the seventh region, and a twelfth region adjacent to the eighth region,
a plurality of the at least one first connection conductors is repeatedly provided in the first direction between the first region and the fifth region,
a plurality of the at least one second connection conductors is repeatedly provided in the first direction between the fifth region and the ninth region, and
the plurality of the at least one first connection conductors and the plurality of the at least one second connection conductors are alternately disposed in the first direction.

7. The semiconductor device according to claim 1, wherein the first annular conductor has a minimum width equal to or less than 1.0 μm.

8. The semiconductor device according to claim 1, wherein the outer peripheral region further includes an insulating layer provided between the first annular conductor and the second annular conductor.

9. The semiconductor device according to claim 1, wherein the first annular conductor includes a first layer and a second layer stacked in a third direction perpendicular to the first face, and a second layer having a chemical composition different from a chemical composition of the first layer.
